(19) United States
(12) Patent Application Publication
(10) Pub. No.: US 2008/0092941 A1
(43) Pub. Date: Apr. 24, 2008

(54) PORTABLE COMPUTER WITH DETACHABLE SOLAR CELL MODULE

(75) Inventor: SZU-WEI KUO, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/781,965

(22) Filed: Jul. 24, 2007

(30) Foreign Application Priority Data
Oct. 24, 2006 (CN) 200610201019.8

(51) Int. Cl. H01L 31/058; H01M 10/44; H05K 5/00

(52) U.S. Cl. 136/248; 320/101; 361/683

(57) ABSTRACT

A portable computer includes a base with a motherboard secured thereto, a display pivotably attached to the base, and a solar cell module. A first connector is installed to the display and electrically connected with the motherboard. The solar cell module has a solar panel. A plurality of photovoltaic sheets is arranged on the solar panel for converting solar energy into electric energy. A second connector is electrically connected with the solar panel. The solar cell module is detachably mounted to the display with the second connector connecting with the first connector such that the electric energy is capable of being transmitted to the motherboard via the first connector and the second connector.

### BACKGROUND OF THE INVENTION

1. Field of the Invention

The present invention relates to portable computers, and more particularly to a portable computer with detachable solar cell module.

2. Description of Related Art

A variety of personal computers are known and widely in use. In recent years, portable computers have been widely accepted by businessmen because of the advantage of high mobility. However, a battery case with rechargeable battery must be provided when a portable computer is to be used away from a source of mains power. Even if a battery case with rechargeable battery is provided, it can only provide a power for a limited length of time, until it must be recharged.

What is desired, therefore, is a portable computer with a solar cell module.

### SUMMARY OF THE INVENTION

In one embodiment, a portable computer includes a base with a motherboard secured thereto, a display pivotably attached to the base, and a solar cell module. A first connector is installed to the display and electrically connected with the motherboard. The solar cell module has a solar panel. A plurality of photovoltaic sheets is arranged on the solar panel for converting solar energy into electric energy. A second connector is electrically connected with the solar panel. The solar cell module is detachably mounted to the display with the second connector connecting with the first connector.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a portable computer in accordance with an embodiment of the present invention, wherein a solar cell module is detached from a display of the portable computer;

FIG. 2 is an assembled view of FIG. 1;

FIG. 3 shows a recharging state of the portable computer of FIG. 2, with the display being opened at an angle relative to a base of the portable computer; and

FIG. 4 shows a use state of the portable computer of FIG. 2, with the display open.

### DETAILED DESCRIPTION OF THE INVENTION

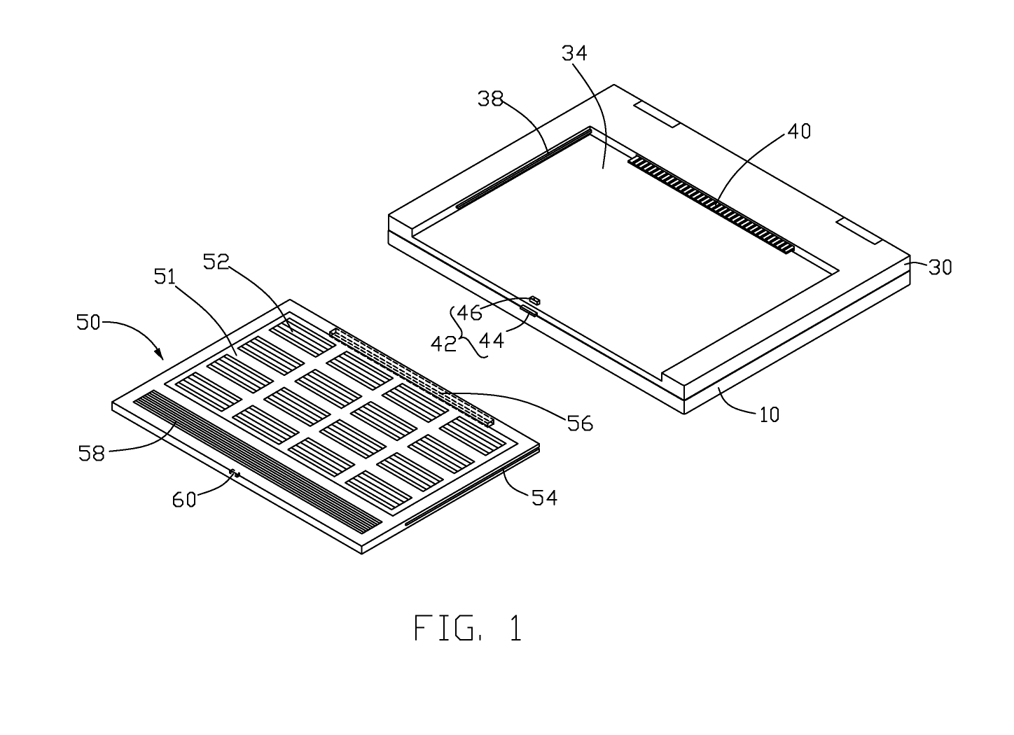

Referring to FIG. 1, in an embodiment of the present invention, a portable computer includes a base 10, a display 30 pivotably secured to the base 10, and a solar cell module 50.

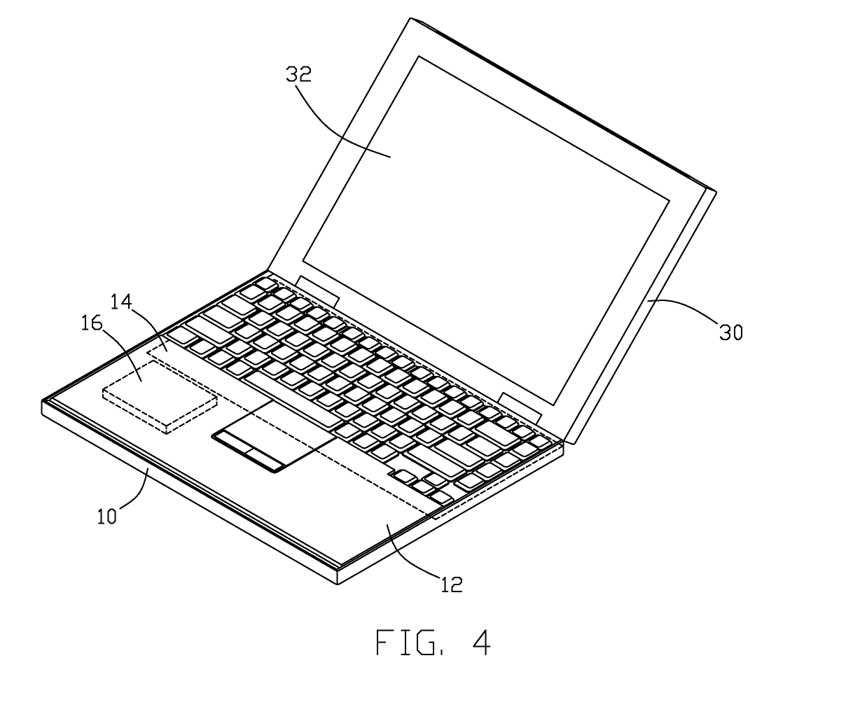

Referring also to FIG. 4, the base 10 includes a chassis 12. A motherboard 14 and a rechargeable battery 16 are mounted to the chassis 12. The rechargeable battery 16 is electrically connected with the motherboard 14.

The display 30 includes a display screen 32. A sunken portion 34 is formed in an outer surface of the display 30, opposite to the display screen 32. A side of the sunken portion 34 at a corresponding side of the display 30, away from a conjunction portion of the base 10 and the display 30, is open to allow the solar cell module 50 to enter into or withdraw from the sunken portion 34. A locking mechanism 42 is installed to the display 30. The locking mechanism 42 includes a press member 44 protruding out from the side of the display 30, and a locking member 46 protruding into the sunken portion 34. Two bulge portions 38 respectively extend along two sidewalls bounding opposite ends of the sunken portion 34. A male connector 40, electrically connected to the motherboard 14, is set at a side of the sunken portion 34 adjacent the conjunction portion of the base 10 and the display 30.

The solar cell module 50 includes a solar panel 51 with a plurality of flat photovoltaic sheets 52 arranged thereon. The photovoltaic sheets 52 convert solar energy into electric energy. The solar panel 51 transforms the electric energy from alternating current (AC) to direct current (DC). Two grooves 54 are respectively defined in two ends of the solar cell module 50, respectively corresponding to the corresponding bulge portions 38 of the sunken portion 34. The solar cell module 50 has a female connector 56 at a side thereof. The female connector 56 is electrically connected to the solar panel 51 of the solar cell module 50. An operation portion 58 with a plurality of ribs is formed at a side of an outer surface of the solar cell module 50, away from the female connector 56, to facilitate fingers pushing the solar cell module 50. A locking hole 60 is defined in the solar cell module 50, corresponding to the locking member 46 of the locking mechanism 42.

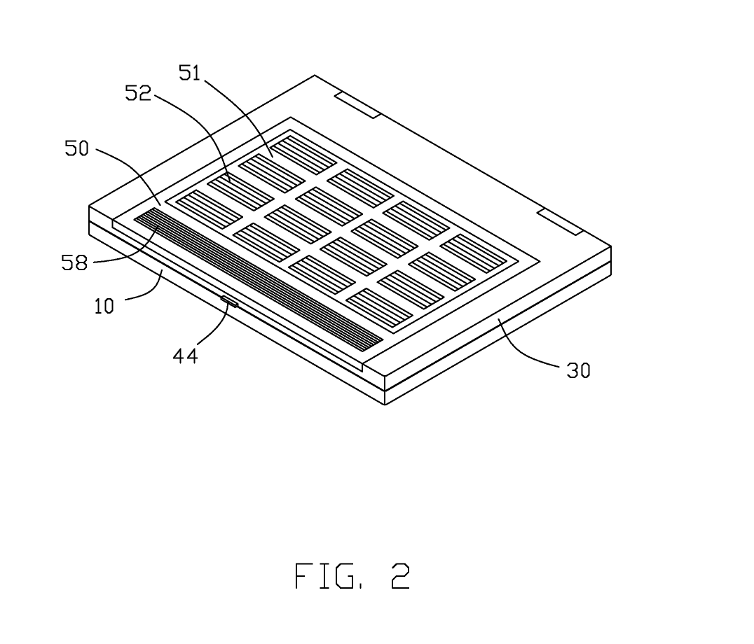

Referring also to FIG. 2, in assembly, the solar cell module 50 is inserted into the sunken portion 34 through the open side of the sunken portion 34. The solar cell module 50 urges the locking member 46 to withdraw from the sunken portion 34. The bulge portions 38 of the sunken portion 34 are respectively slidably engaged with the corresponding grooves 54 of the solar cell module 50. The male connector 40 is plugged into the female connector 56. Thus, the solar cell module 50 is electrically connected with the motherboard 14 by the interconnection of the male and female connectors 40, 56. The locking member 46 is engaged into the locking hole 60. Thus, the solar cell module 50 is firmly secured to the display 30.

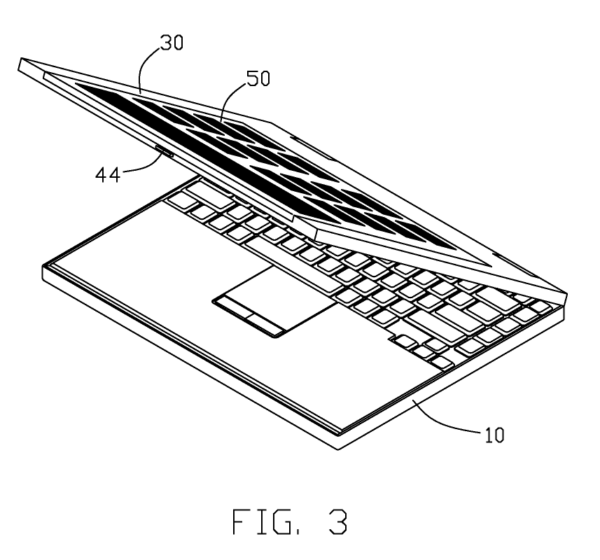

Referring also to FIG. 3, in recharging, the display 30 is exposed to sunlight, and may be opened at an angle relative to the base 10 as needed to achieve greatest exposure to sunlight by the solar panel 51. The photovoltaic sheets 52 convert solar energy into electric energy. The electric energy is transformed from AC to DC by the solar panel 51. The electric energy is transmitted to the motherboard 14 via the female and male connectors 56, 40 to recharge the rechargeable battery 16.

Alternatively, the electric energy from the solar panel 51 may be directly supplied to the mother board 14 to make the portable computer work, and recharge the rechargeable battery 16 synchronously.

If needed, the solar cell module 50 may be replaced with a new one by pushing of the press member 44 to drive the locking member 46 to disengage from the solar cell module 50. The solar cell module 50 can then be removed from the display 30 via operating the operation portion 58.

Additionally, the bulge portions 38 could be respectively formed at the two ends of the solar cell module 50, and the corresponding grooves 54 could be respectively formed at the two ends of the sunken portion 34. In the same way, the locking mechanism 42 could be installed to the solar cell module 50, and the corresponding locking hole 60 could be defined in the display 36.

When the solar cell module 50 is not needed for a time, it can be removed, and a fitted decorative cover is secured to the sunken portion 34.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A portable computer comprising:
a base with a motherboard secured thereto;
a display pivotably attached to the base, a first connector being installed to the display and electrically connected with the motherboard; and
a solar cell module comprising a solar panel, a plurality of photovoltaic sheets being arranged on the solar panel and configured for converting solar energy to electric energy, a second connector being electrically connected with the solar panel, the solar cell module being detachably mounted to the display with the second connector connecting with the first connector.

2. The portable computer as described in claim 1, wherein a sunken portion is formed in an outer surface of the display, and the solar cell module is received in the sunken portion of the display.

3. The portable computer as described in claim 2, wherein a side of the sunken portion is open to allow the solar cell module to slidably enter into and/or withdraw out of the sunken portion of the display.

4. The portable computer as described in claim 3, wherein at least one groove is defined in one of the solar cell module and the sunken portion of the display, and at least one bulge portion is formed in the other one of the solar cell module and the sunken portion of the display to engage with the at least one groove.

5. The portable computer as described in claim 3, wherein a locking hole is defined in one of the solar cell module and the sunken portion of the display, a locking mechanism is installed to the other one of the solar cell module and the sunken portion of the display, and the locking mechanism comprises a locking member being locked into the locking hole to firmly secure the solar cell module, and a press member configured for urging the locking member to release the solar cell module.

6. The portable computer as described in claim 1, wherein an operation portion with a plurality of ribs is formed on the solar cell module spaced from the solar panel and configured for pushing the solar cell module to move.

7. The portable computer as described in claim 1, wherein a rechargeable battery is mounted on the base and electrically connected to the motherboard such that the electric energy is capable of being transmitted to the motherboard via the first connector and the second connector to recharge the rechargeable battery.

8. A portable computer comprising:
a base with a rechargeable battery mounted thereto;
a display pivotably mounted to the base to form a conjunction portion, a first connector being installed to the display and electrically connected with the rechargeable battery; and
a solar cell module comprising a solar panel, and a second connector electrically connected with the solar panel, a plurality of photovoltaic sheets being arranged on the solar panel and configured for converting solar energy into electric energy, the solar cell module being detachably mounted to the display by plugging the first connector into the second connector such that the electric energy recharges the rechargeable battery via the first connector and the second connector.

9. The portable computer as described in claim 8, wherein a locking hole is defined in one of the solar cell module and the display, a locking mechanism is installed to the other one of the solar cell module and the display, and the locking mechanism comprises a locking member being locked into the locking hole to firmly secure the solar cell module, and a press member configured for urging the locking member to withdraw from the locking hole.

10. The portable computer as described in claim 8, wherein at least one groove is defined in one of the solar cell module and the display, and at least one bulge portion is formed in the other one of the solar cell module and the display to engage with the at least one groove.

11. The portable computer as described in claim 8, wherein a sunken portion is formed in an outer surface of the display, a side of the sunken portion is open, and the solar cell module is received in the sunken portion from the open side.

12. A portable computer comprising:
a base comprising a motherboard secured therein and a rechargeable battery electrically connected with the motherboard;
a display pivotably attached to the base, a sunken portion being formed in an outer surface of the display opposing the base, a first connector being installed at one side of the sunken portion and electrically connected with the motherboard; and
a solar cell module being detachably received in the sunken portion, the solar cell module comprising a solar panel with a plurality of photovoltaic sheets configured to convert solar energy into electric energy, and a second connector being electrically connected with the solar panel and configured to connect with the first connector such that the electric energy recharges the rechargeable battery via the first connector and the second connector.

13. The portable computer as described in claim 12, wherein another side of the sunken portion opposing the first connector is open such that the solar cell module is capable of slidably entering into the sunken portion via the open side.

14. The portable computer as described in claim 13, wherein a locking hole is defined in one of the solar cell module and the sunken portion, a locking member is mounted to the other one of the solar cell module and the sunken portion configured to be locked in the locking hole to retain the solar cell module to the sunken portion in a direction along which the solar cell module is capable of slidably entering into the sunken portion, and a press member is connected to the locking member configured for urging the locking member to withdraw from the locking hole.

15. The portable computer as described in claim 14, wherein a pair of grooves is defined at opposite lateral sides of one of the solar cell module and the sunken portion, and a pair of bulges is formed at opposite lateral sides of the other one of the solar cell module and the sunken portion configured to be slidably received in the grooves respectively to retain the solar cell module to the sunken portion in another direction perpendicular to said direction.
